(19) United States
(12) Patent Application Publication
(10) Pub. No.: US 2025/0175168 A1
(43) Pub. Date: May 29, 2025

(54) MULTIPHASE CLOCK SIGNAL GENERATING CIRCUIT AND EYE DIAGRAM GENERATING CIRCUIT

(71) Applicant: Realtek Semiconductor Corp., Hsinchu (TW)

(72) Inventor: Tse-Hung Chen, Hsinchu (TW)

(73) Assignee: Realtek Semiconductor Corp., Hsinchu (TW)

(21) Appl. No.: 18/633,489

(22) Filed: Apr. 11, 2024

(30) Foreign Application Priority Data
Nov. 29, 2023 (TW) 112146333

(51) Int. Cl. H03K 5/133; H03K 5/24; H03K 21/02

(52) U.S. Cl. CPC H03K 5/133; H03K 5/249; H03K 21/026

(57) ABSTRACT

A multi-phase clock signal generating circuit, configured to generate a plurality of output clock signals with different phases, comprising: a charge pump, configured to generate a control voltage according to a reference clock signal and a target clock signal; a delay circuit, comprising a delay chain with a plurality of delay units, configured to generate a plurality of candidate clock signals and the target clock signal according to the control voltage; and a phase selecting circuit, configured to select at least two of the candidate clock signals as the output signals.

### BACKGROUND OF THE INVENTION

### 1. Field of the Invention

The present invention relates to a multiphase clock signal generating circuit and an eye diagram generating circuit, and particularly relates to a multiphase clock signal generating circuit and an eye diagram generating circuit which can generate clock signals with uniform phases.

### 2. Description of the Prior Art

In the conventional technology, the signal quality of the circuit may be represented by an eye diagram. The eye diagram can be generated by scanning the signal of the circuit under test using clock signals with different phases (i.e., multi-phase clock signals). In the prior art, a phase interpolation circuit is usually used to generate multi-phase clock signals. However, the phase interpolation circuit may be limited by the RC charge and discharge time, or affected by circuit process drift, and therefore cannot generate multi-phase clock signals with uniform phases. In other words, the phase differences of adjacent clock signals should ideally be equal, but in fact, the phase differences of different adjacent clock signals are always different.

### SUMMARY OF THE INVENTION

One objective of the present invention is to provide a multi-phase clock signal generating circuit which can generate multi-phase clock signals with uniform phases.

Another objective of the present invention is to provide an eye diagram generating circuit which can generate an accurate eye diagram.

One embodiment of the present invention discloses a multi-phase clock signal generating circuit, configured to generate a plurality of output clock signals with different phases, comprising: a charge pump, configured to generate a control voltage according to a reference clock signal and a target clock signal; a delay circuit, comprising a delay chain with a plurality of delay units, configured to generate a plurality of candidate clock signals and the target clock signal according to the control voltage; and a phase selecting circuit, configured to select at least two of the candidate clock signals as the output signals.

Another embodiment of the present invention provides an eye diagram generating circuit with a comparator and a multi-phase clock signal generating circuit. The comparator uses a plurality of output clock signals with different phases to scan a data signal to generate an eye diagram. The multi-phase clock signal generating circuit comprising: a charge pump, configured to generate a control voltage according to a reference clock signal and a target clock signal; a delay circuit, comprising a delay chain with a plurality of delay units, configured to generate a plurality of candidate clock signals and the target clock signal according to the control voltage; and a phase selecting circuit, configured to select at least two of the candidate clock signals as the output signals.

In view of foregoing embodiments, multi-phase clock signals with a more uniform phase distribution can be generated, and such multi-phase clock signals can be used to generate a more accurate eye diagram.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a multi-phase clock signal generating circuit according to one embodiment of the present invention.

FIG. 2 and FIG. 3 are detail circuit diagrams of the multi-phase clock signal generating circuit shown in FIG. 1, according to different embodiments of the present invention.

FIG. 4 and FIG. 5 are schematic diagrams of the delay units shown in FIG. 2, according to different embodiments of the present invention.

FIG. 6 is a schematic diagram of an eye diagram generating circuit according to one embodiment of the present invention.

FIG. 7 is a wave chart illustrating operations of the circuit shown in FIG. 6, according to one embodiment of the present invention.

### DETAILED DESCRIPTION

In the following descriptions, several embodiments are provided to explain the concept of the present application. The term “first”, “second”, “third” in following descriptions are only for the purpose of distinguishing different one elements, and do not mean the sequence of the elements. For example, a first device and a second device only mean these devices can have the same structure but are different devices.

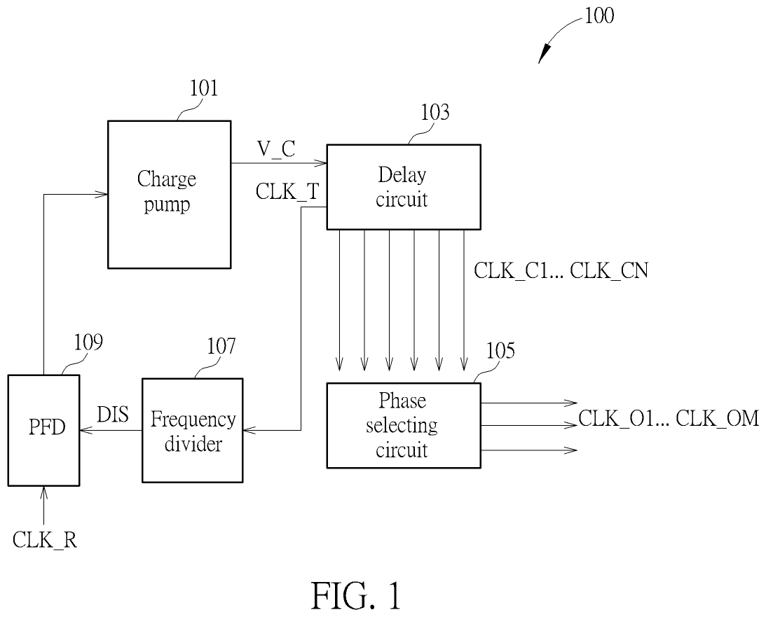

FIG. 1 is a block diagram of a multi-phase clock signal generating circuit 100 according to one embodiment of the present invention, which is configured to generate a plurality of output clock signals with different phases. As shown in FIG. 1, the multi-phase clock signal generating circuit 100 comprises a charge pump 101, a delay circuit 103 and a phase selecting circuit 105. The charge pump 101 generates a control voltage V_C according to a reference clock signal CLK_R and a target clock signal CLK_T. The delay circuit 103 comprises a delay chain (not shown in FIG. 1) with a plurality of delay units for generating a plurality of candidate clock signals CLK_C1 . . . . CLK_CN and a target clock signal CLK_T according to the control voltage V_C. The phase selecting circuit 105 is configured to select at least two signals among the candidate clock signals CLK_C1 . . . . CLK_CN as the output clock signals CLK_O1 . . . . CLK_OM. The reference clock signal CLK_R can be provided by different sources corresponding to different circuit designs or requirements. In one embodiment, the reference clock signal CLK_R is provided by a clock data recovery circuit (CDR) inside a receiving circuit to assist in scanning the phase of the clock signal and synchronization of the phases of the data signal to be measured. Details about the scanning clock signals and data signals will be described in the following embodiments.

In the embodiment of FIG. 1, the multi-phase clock signal generating circuit 100 further comprises a frequency divider 107 and a phase frequency detector 109. The aforementioned “the charge pump 101 is configured to generate a control voltage V_C according to a reference clock signal CLK_R and a target clock signal CLK_T” is implemented by the frequency divider 107 and the phase frequency detector 109. The frequency divider 107 is configured to receive the target clock signal CLK_T and perform a frequency division operation on the target clock signal CLK_T to generate a frequency divided signal DIS. The phase frequency detector 109 is configured to control the charge pump 101 according to the frequency divided signal DIS and the reference clock signal CLK_R. In one embodiment, if the phase of the frequency divided signal DIS leads or falls behind the reference clock signal CLK_R, the charge pump 101 will correspondingly change the control voltage V_C to control the delay amount of the delay circuit 103 to change a phase of the target clock signal CLK_T.

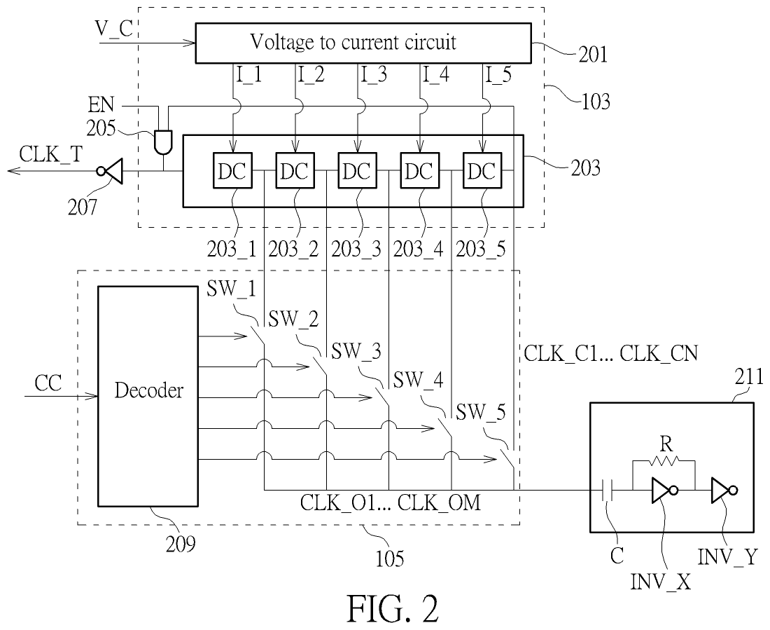

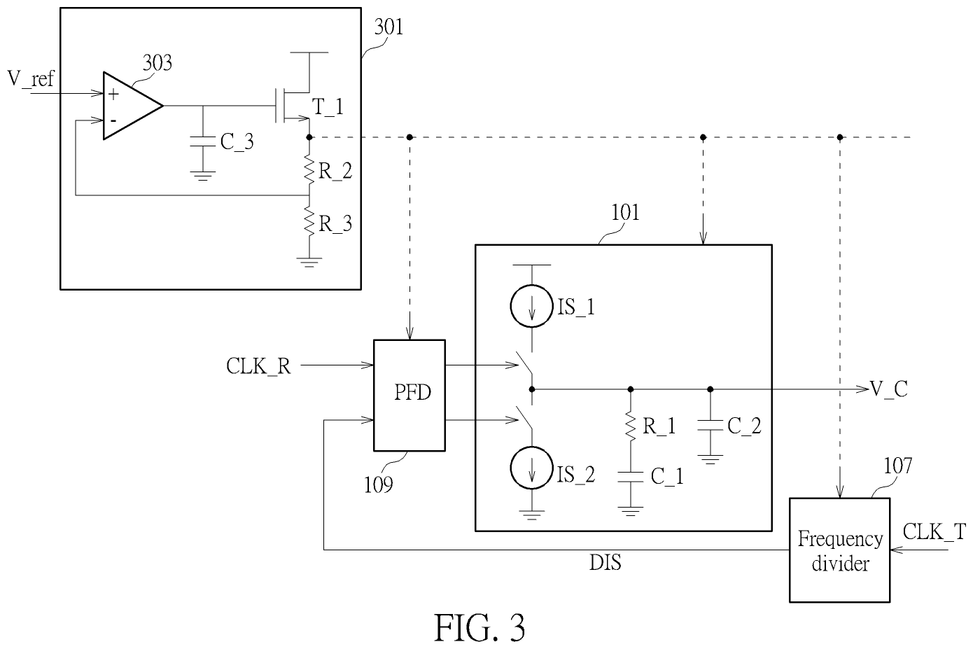

Each circuit shown in FIG. 1 can be implemented by a variety of different circuits. FIG. 2 and FIG. 3 are detail circuit diagrams of the multi-phase clock signal generating circuit shown in FIG. 1, according to different embodiments of the present invention. As shown in FIG. 2, the delay circuit 103 comprises a voltage to current circuit 201 and a delay line 203. The delay line 203 comprises a plurality of delay cells 203_1, 203_2, 203_3, 203_4 and 203_5. However, the number of delay units is not limited to the embodiment shown in FIG. 2. The voltage to current circuit 201 is configured to receive the control voltage V_C to generate a plurality of control currents I_1, I_2, I_3, I_4 and I_5 for the delay units 203_1, 203_2, 203_3, 203_4 and 203_5. The delay units 203_1, 203_2, 203_3, 203_4 and 203_5 can respectively generate different delay amounts according to the control currents I_1, I_2, I_3, I_4 and I_5.

In the embodiment of FIG. 2, the delay circuit 103 further comprises an NAND gate 205. The NAND gate 205 comprises a first input terminal, a second input terminal and an output terminal. The first input terminal is configured to receive the enable signal EN. The second input terminal is coupled to the output terminal of the last delay unit (for example, delay unit 203_5). The output terminal is coupled to the input terminal of the first delay unit (for example, delay unit 203_1). In addition, the delay circuit 103 further comprises an inverter 207 for inverting the output of the NAND gate 205 as the target clock signal CLK_T. The phase selecting circuit 105 comprises a decoder 209 and a plurality of switches SW_1, SW_2, SW_3, SW_4 and SW_5. The decoder 209 turns on at least one of the switches SW_1, SW_2, SW_3, SW_4 and SW_5 according to a control code CC to select at least one of the candidate clock signals CLK_C1 . . . . CLK_CN as the output clock signal CLK_O1 . . . . CLK_OM. The NAND gate 205 can be used to control whether the delay chain 203 generates the candidate clock signals CLK_C1 . . . . CLK_CN.

In the embodiment of FIG. 2, the multi-phase clock signal generating circuit 100 further comprises a self-bias buffer 211 for buffering the output clock signals CLK_O1 . . . . CLK_OM respectively. The self-bias buffer 211 can provide better fan-out coefficient, and may be implemented by a variety of circuits. In the example of FIG. 2, the self-bias buffer 211 comprises a resistor R, a capacitor C and inverters INV_X and INV_Y, but it is not limited thereto.

In the embodiment of FIG. 3, the charge pump 101 comprises current sources IS_1, IS_2, capacitors C_1, C_2 and a resistor R_1, but the charge pump 101 can also be implemented by other circuits. In the embodiment of FIG. 3, the multi-phase clock signal generating circuit 100 further comprises a LDO (low-dropout linear regulator) 301 for providing power. Please also note that although in the embodiment of FIG. 3, the LDO 301 provides power to the charge pump 101, the frequency divider 107 and the phase frequency detector 109, it can also provide power to other circuits in the phase clock signal generating circuit 100. The LDO 301 can provide a power signal with less noise. In the embodiment of FIG. 3, the LDO 301 comprises a comparator 303, a capacitor C_3, a transistor T_1 and resistors R_2 and R_3, but is not limited thereto.

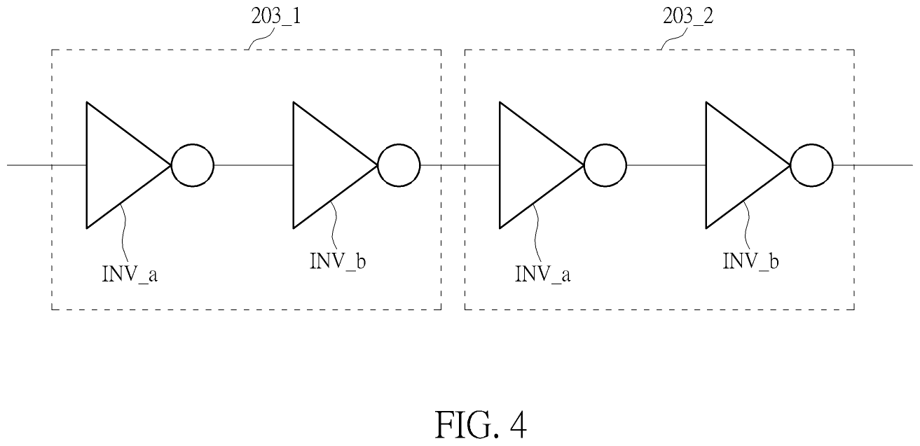

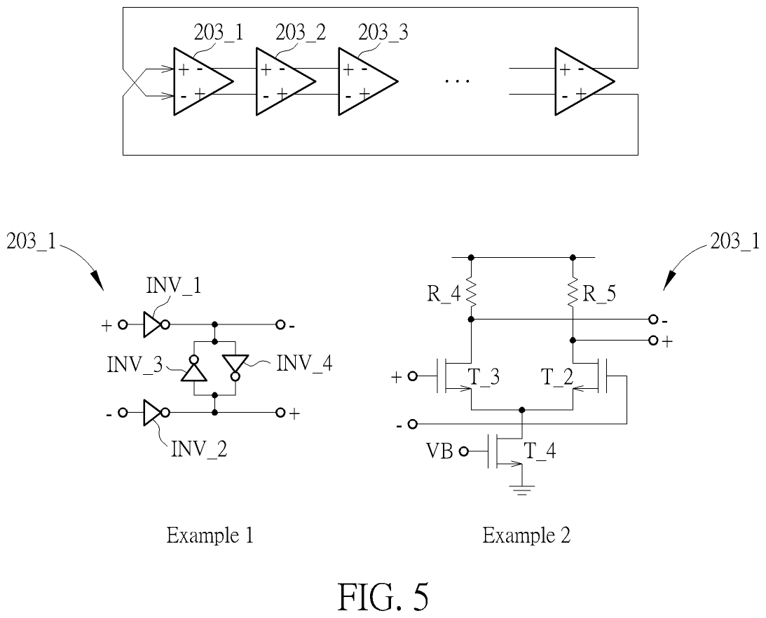

The delay units 203_1, 203_2, 203_3, 203_4 and 203_5 shown in FIG. 2 can be implemented by a variety of circuits. FIG. 4 and FIG. 5 are schematic diagrams of the delay units shown in FIG. 2, according to different embodiments of the present invention. In one embodiment, each of the delay units comprises a plurality of single end inverters. For example, in the embodiment of FIG. 4, delay units 203_1 and 203_2 comprise inverters INV_a and INV_b respectively. Other delay units may also have the same circuit structure as the delay units 203_1 and 203_2 in FIG. 4. In one embodiment, the delay units 203_1 and 203_2 respectively comprise at least one FinFET (Fin Field-Effect Transistor), that is, at least one of the transistors in the inverter INV_a or INV_b is a FinFET. FinFET is a three-dimensional transistor that can improve circuit control and reduce leakage current, shorten the gate length of the transistor, have higher saturation currents and transduction, and lower parasitic capacitance. Therefore, the FinFET can have a very high cutoff frequency, allowing the multi-phase clock signal generating circuit 100 of the present invention to generate a multi-phase clock signal with high frequency. In addition to the delay unit, FinFETs can also be used as transistors in other circuits.

In one embodiment, the delay units are respectively a differential delay unit. For example, in the embodiment of FIG. 5, the delay units 203_1, 203_2 and 203_3 are respectively a differential delay unit. Differential delay units can be implemented by a variety of circuits. In one embodiment, each of the delay units 203_1, 203_2 and 203_3 in FIG. 5 is a pseudo differential delay unit, which may also comprise at least one FinFET respectively. A pseudo differential delay unit may comprise multiple flip-flops. For example, in Example 1 of FIG. 5, the delay unit 203_1 comprises inverters INV 1, INV 2, INV 3 and INV 4. The pseudo differential delay unit can also comprise transistors and resistors. For example, in Example 2 of FIG. 5, the delay unit 203_1 comprises transistors T_2, T_3, and T_4 and resistors R_4 and R_5.

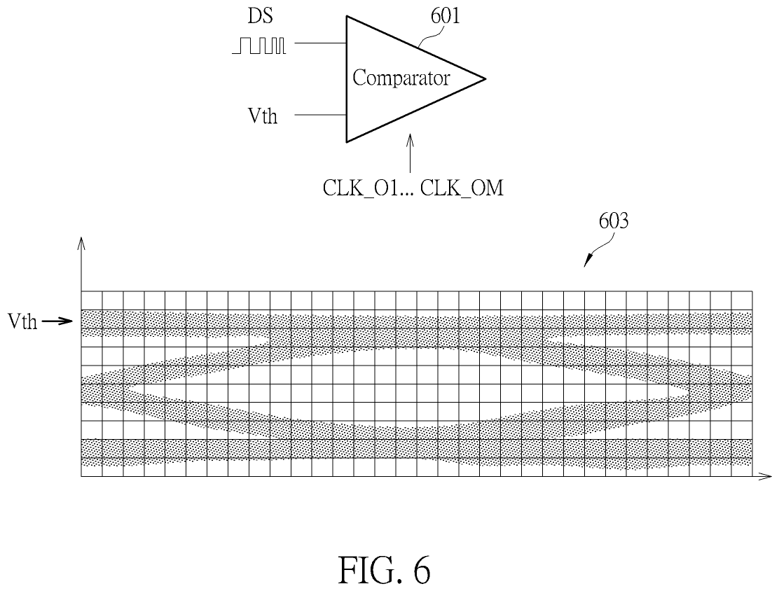

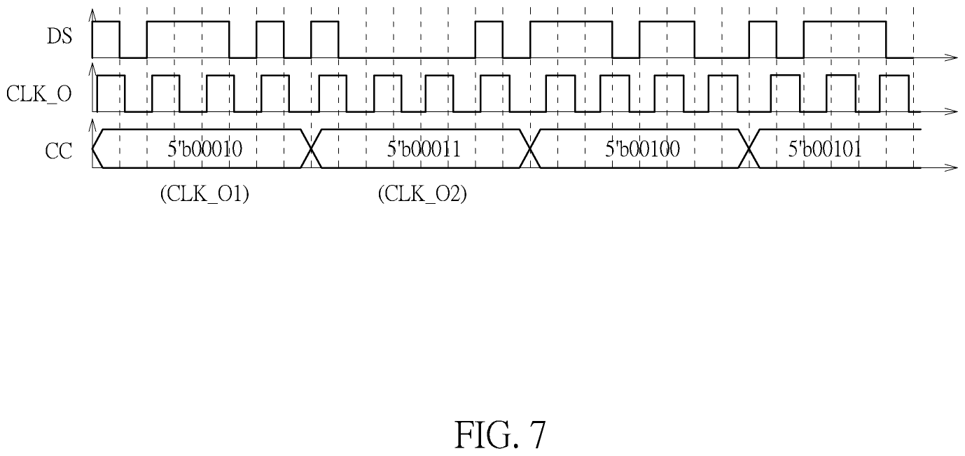

The output clock signals CLK_O1 . . . . CLK_OM generated in the foregoing embodiments can be used to generate eye diagrams. FIG. 6 is a schematic diagram of an eye diagram generating circuit according to one embodiment of the present invention, and FIG. 7 is a wave chart illustrating operations of the circuit shown in FIG. 6, according to one embodiment of the present invention. Please refer to FIG. 1, FIG. 6 and FIG. 7 together to understand the concept of the present invention for more clarity. In the embodiment of FIG. 6, the eye diagram generating circuit further comprises a comparator 601 in addition to the circuit of FIG. 1. The comparator 601 receives the output clock signals CLK_O1 . . . . CLK_OM shown in FIG. 1 to generate the eye diagram 603. Each grid on the horizontal axis in the eye diagram 603 corresponds to a different output clock signal. For example, the first grid in the horizontal axis corresponds to the output clock signal CLK_O1, that is, the clock signal CLK_O1 is used to scan the data signal DS. Also, the second grid in the horizontal axis corresponds to the output clock signal CLK_O2, that is, the clock signal CLK_O2 is used to scan the data signal DS. In the embodiment of FIG. 6, the horizontal axis has a total of 32 grids, that is, there are 32 output clock signals CLK_O1 . . . . CLK_O32 with different phases. In such embodiment, the delay chain 203 in FIG. 2 comprises at least 31 delay cells. In the embodiment of FIG. 6, the comparator 601 further receives a voltage Vth, which is used to determine which part of the data signal DS is to be scanned. For example, when the voltage Vth is the lowest, the bottom row is scanned, and when the voltage Vth increases by one level, the second to last row is scanned. The voltage Vth will gradually increase until the required portion of the data signal DS is scanned.

In the wave chart shown in FIG. 7, the control code CC received by the decoder 209 in FIG. 2 corresponds to different output clock signals. For example, when the control code CC is 5′b00010, the output clock signal CLK_O1 will be selected for scanning, and when the control code CC is 5′b00011, the clock signal CLK_O2 will be selected for scanning. The output clock signals CLK_O1 . . . . CLK_O32 generated by the foregoing embodiments have a relatively uniform phase distribution, that is, differences of the phase differences between adjacent output clock signals CLK_O1 . . . . CLK_O32 is 0 or extremely small. For example, difference of the phase difference between the output clock signal CLK_O1 and its next output clock signal CLK_O2 and the phase difference between the output clock signal CLK_O2 and its next output clock signal CLK_O3 are 0 or extremely small. Therefore, the eye diagram which is generated by using the output clock signals generated by the aforementioned embodiments is more accurate. However, please note that the output clock signals generated by the present invention can be used in other eye diagram generation methods and is not limited to the methods described in FIGS. 6 and 7. In addition, the output clock signals generated by the invention can be used in other applications and is not limited to generate eye diagrams.

In view of foregoing embodiments, multi-phase clock signals with a more uniform phase distribution can be generated, and such multi-phase clock signals can be used to generate a more accurate eye diagram.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A multi-phase clock signal generating circuit, configured to generate a plurality of output clock signals with different phases, comprising:
a charge pump, configured to generate a control voltage according to a reference clock signal and a target clock signal;
a delay circuit, comprising a delay chain with a plurality of delay units, configured to generate a plurality of candidate clock signals and the target clock signal according to the control voltage; and
a phase selecting circuit, configured to select at least two of the candidate clock signals as the output signals.

2. The multi-phase clock signal generating circuit of claim 1, wherein the delay circuit further comprises:
a voltage to current circuit, configured to receive the control voltage to generate a plurality of control currents to the delay units.

3. The multi-phase clock signal generating circuit of claim 1, further comprising:
a NAND gate, comprising:
a first input terminal, configured to receive an enable signal;
a second input terminal, coupled to an output terminal of a last one of the delay units; and
an output terminal, coupled to an input terminal of a first one of the delay units.

4. The multi-phase clock signal generating circuit of claim 1, further comprising:
a frequency divider, configured to receive the target clock signal to generate a frequency-divided signal; and
a phase frequency detector, configured to control the charge pump according to the frequency-divided signal and the reference clock signal.

5. The multi-phase clock signal generating circuit of claim 1, wherein the delay units respectively comprises a plurality of single end inverters.

6. The multi-phase clock signal generating circuit of claim 5, wherein the delay units respectively comprises at least one FinFET (Fin Field-Effect Transistor).

7. The multi-phase clock signal generating circuit of claim 1, wherein the delay units are differential delay units.

8. The multi-phase clock signal generating circuit of claim 7, wherein the delay units are pseudo differential delay units, and the delay units are inverters respectively comprising at least one FinFET.

9. The multi-phase clock signal generating circuit of claim 1, further comprising:
a LDO (Low-dropout regulator), configured to provide power to the charge pump, the delay chain and the phase selecting circuit.

10. The multi-phase clock signal generating circuit of claim 1, further comprising:
a self-bias buffer, configured to buffer the output clock signals.

11. An eye diagram generating circuit, comprising:
a comparator, configured to use a plurality of output clock signals with different phases to scan a data signal, to generate an eye diagram; and
a multi-phase clock signal generating circuit, comprising:
a charge pump, configured to generate a control voltage according to a reference clock signal and a target clock signal;
a delay circuit, comprising a delay chain with a plurality of delay units, configured to generate a plurality of candidate clock signals and the target clock signal according to the control voltage; and
a phase selecting circuit, configured to select at least two of the candidate clock signals as the output signals.

12. The eye diagram generating circuit of claim 11, wherein the delay circuit further comprises:
a voltage to current circuit, configured to receive the control voltage to generate a plurality of control currents to the delay units.

13. The eye diagram generating circuit of claim 11, further comprising:
a NAND gate, comprising:
a first input terminal, configured to receive an enable signal;
a second input terminal, coupled to an output terminal of a last one of the delay units; and
an output terminal, coupled to an input terminal of a first one of the delay units.

14. The eye diagram generating circuit of claim 11, further comprising:
a frequency divider, configured to receive the target clock signal to generate a frequency-divided signal; and
a phase frequency detector, configured to control the charge pump according to the frequency-divided signal and the reference clock signal.

15. The eye diagram generating circuit of claim 11, wherein the delay units respectively comprises a plurality of single end inverters.

16. The eye diagram generating circuit of claim 15, wherein the delay units respectively comprises at least one FinFET.

17. The eye diagram generating circuit of claim 11, wherein the delay units are differential delay units.

18. The eye diagram generating circuit of claim 17, wherein the delay units are pseudo differential delay units, and the delay units are inverters respectively comprising at least one FinFET.

19. The eye diagram generating circuit of claim 11, further comprising:
a LDO, configured to provide power to the charge pump, the delay chain and the phase selecting circuit.

20. The eye diagram generating circuit of claim 11, further comprising:
a self-bias buffer, configured to buffer the output clock signals.
